(19) United States
(12) Patent Application Publication
(10) Pub. No.: US 2015/0221529 A1
(43) Pub. Date: Aug. 6, 2015

(54) GAS SUPPLY METHOD AND THERMAL TREATMENT METHOD

(71) Applicant: TOKYO ELECTRON LIMITED, Tokyo (JP)

(72) Inventors: Haruhiko FURUYA, Nirasaki City (JP); Hiromi SHIMA, Nirasaki City (JP); Yusuke TACHINO, Nirasaki City (JP)

(21) Appl. No.: 14/687,071

(22) Filed: Apr. 15, 2015

Related U.S. Application Data
(62) Division of application No. 13/467,184, filed on May 9, 2012.

(30) Foreign Application Priority Data
May 10, 2011 (JP) 2011-105145

(51) Int. Cl. H01L 21/67; G05D 16/00

(52) U.S. Cl. CPC H01L 21/67017; G05D 16/00; H01L 21/67115

(57) ABSTRACT

A gas supply apparatus including a raw material gas supply system supplying a raw material gas inside a raw material storage tank into the processing container by the carrier gas, the gas supply apparatus includes: a carrier gas passage introducing the carrier gas into the raw material storage tank, a raw material gas passage connecting the raw material storage tank and the processing container to supply the carrier gas and the raw material gas; a pressure control gas passage being connected to the raw material gas passage to supply the pressure control gas; and a valve control unit controlling an opening/closing valve to perform for starting a supply of the pressure control gas into the processing container and simultaneously starting supply of the raw material gas into the processing container from the raw material storage tank, and stopping the supply of the pressure control gas.

### CROSS-REFERENCE TO RELATED PATENT APPLICATIONS

This application is a divisional application of prior U.S. application Ser. No. 13/467,184, filed on May 9, 2012, the entire contents of which are incorporated herein by reference, and this application claims the benefit of Japanese Patent Application No. 2011-105145, filed on May 10, 2011 in the Japan Patent Office, the disclosure of which is incorporated herein in its entirety by reference.

### BACKGROUND OF THE INVENTION

1. Field of the Invention

The present invention relates to a thermal treatment apparatus for performing thermal treatment on an object to be processed such as a semiconductor wafer, and a gas supply apparatus, a thermal treatment method, and a gas supply method that are used together with the thermal treatment apparatus.

2. Description of the Related Art

In general, in order to manufacture a semiconductor integrated circuit, various processes, for example, a film-forming process, an etching process, an oxidization process, a diffusing process, a modification process, or a natural oxidization film removing process, are performed on a semiconductor wafer constituted of a silicon substrate or the like. The above-described processes are performed by using a single-wafer-type processing apparatus for individually processing each wafer or a batch-type processing apparatus for simultaneously processing a plurality of wafers. For example, when the above-described processes are performed by a vertical batch-type processing apparatus that is described in Patent Reference 1 or the like, a plurality of semiconductor wafers are transferred from a cassette capable of accommodating, e.g., about 25 sheets of semiconductor wafers, to a vertical-type wafer boat and then are supported in a multistage manner.

About 30 to 150 sheets of wafers may be placed on the wafer boat according to, for example, a size of a semiconductor wafer. The wafer boat is carried (loaded) from the bottom of a processing container into the processing container from which air may be exhausted, and then an inside of the processing container is held airtight. A predetermined thermal treatment process is performed by controlling various process conditions such as a flow rate of a processing gas, processing pressure, a processing temperature, etc.

For example, regarding a film-forming process, various metal materials, e.g., zirconium (Zr) or ruthenium (Ru), which are not used in a method of manufacturing a conventional semiconductor integrated circuit, have been recently used to improve the characteristics of a semiconductor integrated circuit. Such metal materials, in general, are combined with an organic material to be used as a raw material of a liquid or solid organic metal material. The raw material is accommodated in an airtight container and is heated to generate a raw material gas, and the raw material gas is transferred by a carrier gas, such as a rare gas, to be used in the film-forming process, or the like (Patent Reference 2).

However, a diameter of a semiconductor wafer has been recently gradually increased, and the diameter of the semiconductor wafer is, for example, about 300 mm, and a semiconductor wafer with a diameter of 450 mm is expected to be obtained in the future. Also, as devices become smaller, there is a need to form a capacitor insulating film of a dynamic random access memory (DRAM) having a high-aspect-ratio structure with a good step coverage and to flow a large amount of raw material gas in terms of improvement of a throughput of the film-forming process. In addition, in order to increase a flow rate of the raw material gas, a heating amount of a raw material is increased or a large amount of carrier gas is flowed.

However, in order to increase a flow rate of the raw material gas, if film formation is performed under a process condition in which a flow rate of a carrier gas is increased, at the beginning of the film formation, a large amount of carrier gas and a large amount of raw material gas are supplied when the inside of the processing container is in a vacuum suction state. Accordingly, a great differential pressure is instantaneously generated between the processing container and a supply system of the carrier gas, and the raw material gas changes into mist state due to the differential pressure. The raw material gas of the mist state is attached onto an inner wall of a gas passage or to a surface of the semiconductor wafer, and thus, the raw material gas is to be particles.

In particular, when an atomic layer deposition (ALD) process in which a raw material gas is intermittently repeatedly supplied and stops from being supplied is performed to form a film, generation of the above-described particles cannot be avoided whenever the supply of the raw material gas is started, and thus, an early-stage solution is required.

3. Prior Art Reference

(Patent Reference 1) Japanese Laid-Open Patent Publication No. Hei 06-275608

(Patent Reference 2) Japanese (Unexamined) Patent Application Publication (Translation of PCT Application) No. 2002-525430

### SUMMARY OF THE INVENTION

To solve the above problems, the present invention provides a gas supply apparatus, a thermal treatment apparatus, a gas supply method, and a thermal treatment method that are used to prevent generation of particles by decreasing a differential pressure between a supply system of a carrier gas and a processing container when the supply of a raw material gas is started.

According to an aspect of the present invention, a gas supply apparatus including a raw material gas supply system for supplying a raw material gas generated from a raw material inside a raw material storage tank into a processing container for performing thermal treatment on an object to be processed by using a carrier gas, the gas supply apparatus includes: a carrier gas passage which includes an opening/closing valve provided in a middle of the carrier gas passage to introduce the carrier gas into the raw material storage tank; a raw material gas passage which connects the raw material storage tank and the processing container and in which an opening/closing valve is provided in a middle of the raw material gas passage to supply the raw material gas together with the carrier gas; a pressure control gas passage in which an opening/closing valve is provided in a middle of the pressure control gas passage and which is connected to the raw material gas passage to supply a pressure control gas;

and a valve control unit that controls each of the opening/closing valves so as to perform a first process of starting supply of the pressure control gas into the processing container and simultaneously starting supply of the raw material gas into the processing container from the raw material storage tank by using the carrier gas, and then to perform a second process of stopping the supply of the pressure control gas.

As such, in the gas supply apparatus including the raw material gas supply system for supplying the raw material gas generated from the raw material inside the raw material storage tank into the processing container for performing thermal treatment on an object to be processed by using the carrier gas, the first process of starting supply of the pressure control gas into the processing container and simultaneously starting supply of the raw material gas into the processing container from the raw material storage tank by using the carrier gas is performed, and then the second process of stopping the supply of the pressure control gas is performed. Thus, when the supply of the raw material gas is started, a differential pressure between a supply system of the carrier gas and the processing container may be decreased, thereby preventing generation of particles.

According to another aspect of the present invention, a thermal treatment apparatus for performing thermal treatment on an object to be processed, the thermal treatment apparatus includes: a processing container which accommodates the object to be processed; a holding unit which holds the object to be processed inside the processing container; a heating unit which heats the object to be processed; a vacuum exhaust system which exhausts atmosphere inside the processing container; and the gas supply apparatus.

According to another aspect of the present invention, a gas supply method used by a gas supply apparatus which includes a raw material storage tank for storing a raw material, a carrier gas passage for introducing a carrier gas into the raw material storage tank, a raw material gas passage for connecting the raw material storage tank and a processing container for performing thermal treatment on an object to be processed, and a raw material gas supply system connected to the raw material gas passage and including a pressure control gas passage for supplying a pressure control gas, the gas supply method includes: a first process of starting supply of the pressure control gas into the processing container and simultaneously starting supply of a raw material gas into the processing container from the raw material storage tank by using the carrier gas; and a second process of stopping the supply of the pressure control gas after performing the first process.

According to another aspect of the present invention, a thermal treatment method used to perform thermal treatment on an object to be processed is performed by using the gas supply method.

Additional objects and advantages of the invention will be set forth in the description which follows, and in part will be obvious from the description, or may be learned by practice of the invention.

The objects and advantages of the invention may be realized and obtained by means of the instrumentalities and combinations particularly pointed out hereinafter.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a vertical cross-sectional view of an embodiment of a thermal treatment apparatus according to the present invention;

FIG. 2 is a horizontal cross-sectional view of the thermal treatment apparatus, wherein a heating unit is omitted;

FIG. 3 is a flowchart for describing a thermal treatment method including an embodiment of a gas supply method according to the present invention;

FIGS. 4A and 4B are schematic diagrams for describing flow of gas using the gas supply method of FIG. 3;

FIG. 5 is a flowchart for describing a thermal treatment method including another embodiment of a gas supply method according to the present invention;

FIGS. 6A through 6C are schematic diagrams for describing flow of gas using the gas supply method of FIG. 5; and

FIG. 7 is a schematic diagram for describing flow of gas of a preceding process using another embodiment of a gas supply method according to the present invention.

### DETAILED DESCRIPTION OF THE INVENTION

An embodiment of the present invention achieved on the basis of the findings given above will now be described with reference to the accompanying drawings. In the following description, the constituent elements having substantially the same function and arrangement are denoted by the same reference numerals, and a repetitive description will be made only when necessary.

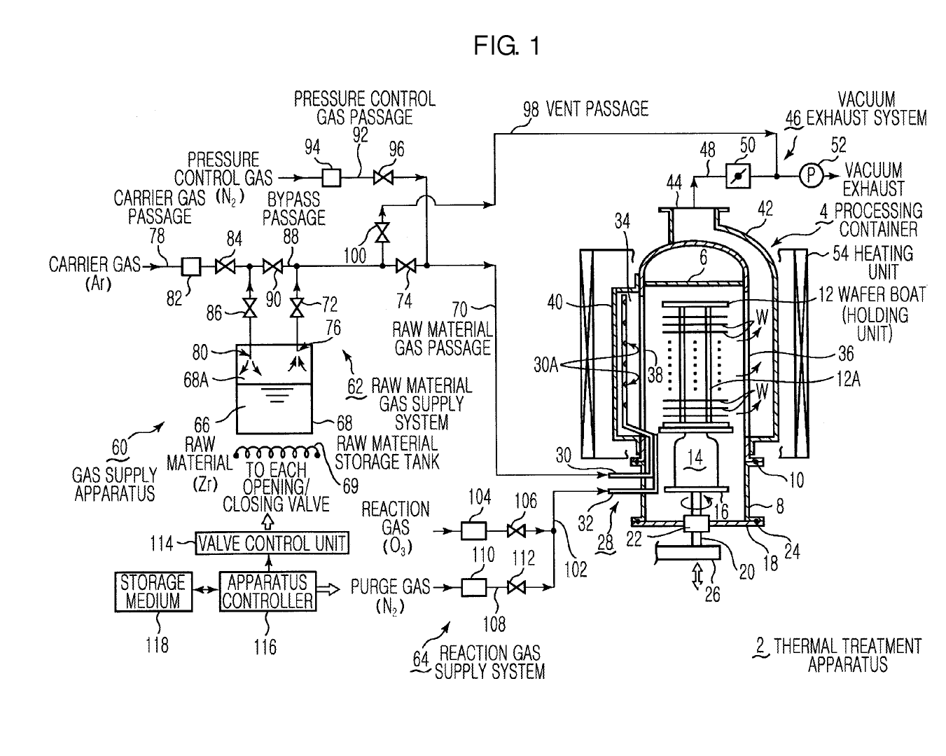

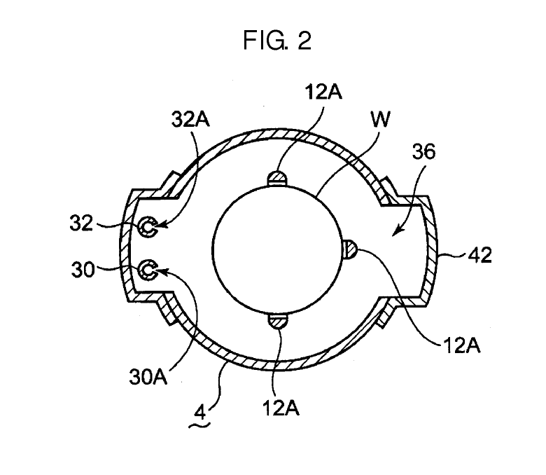

Hereinafter, the present invention will be described in detail by explaining exemplary embodiments of the invention with reference to the attached drawings. FIG. 1 is a vertical cross-sectional view of an embodiment of a thermal treatment apparatus according to the present invention. FIG. 2 is a horizontal cross-sectional view of the thermal treatment apparatus of FIG. 1, wherein a heating unit is omitted.

As shown in FIGS. 1 and 2, the thermal treatment apparatus 2 includes a cylindrical processing container 4 having a ceiling and a lower end that is opened. The processing container 4 is formed of, e.g., quartz. A ceiling plate 6 formed of quartz is provided and sealed in the ceiling inside the processing container 4. A manifold 8 molded into a cylindrical shape and formed of, e.g., stainless steel, is connected to a lower opening portion of the processing container 4 via a sealing member 10 such as an O-ring. Alternatively, the processing container may be formed of quartz to have a cylindrical shape, without providing the manifold 8 formed of stainless steel.

The lower end of the processing container 4 is supported by the manifold 8, a wafer boat 12 formed of quartz may move up and down to be inserted into and pulled out from a lower side of the manifold 8, and a plurality of semiconductor wafers W (also, hereinafter referring to as wafers W), which are objects to be processed, are placed in a multistage manner on the wafer boat 12 as a holding unit. In the current embodiment, a plurality of pillars 12A of the wafer boat 12 may support, for example, about 50 to 100 sheets of semiconductor wafers W having a diameter of 300 mm and being provided at approximately the same pitch in a multistage manner.

The wafer boat 12 is placed on a table 16 via a thermos vessel 14 formed of quarts, and the table 16 is supported on a rotational shaft 20 penetrating a cover unit 18 formed of, e.g., stainless steel, for opening and closing the lower opening portion of the manifold 8. A magnetic fluid seal 22 is provided in a penetration portion of the rotational shaft 20 to support the rotational shaft 20 to be sealed airtight and rotated. A sealing member 24, for example, an O-ring, is provided at a peripheral portion of the cover unit 18 and the lower end portion of the manifold 8 to maintain a sealing property inside the processing container 4.

The rotational shaft 20 is attached to a leading end of an arm 26 supported by an elevation mechanism (not shown) such as a boat elevator and allows the wafer boat 12, the cover unit 18, etc., to move up and down collectively to be inserted into and pulled out from the processing container 4. The table 16 is fixedly provided adjacent to the cover unit 18, and processing of the wafers W may be performed without rotating the wafer boat 12. A gas inlet portion 28 is provided in the processing container 4.

In detail, the gas inlet portion 28 includes a plurality of gas distribution nozzles 30 and 32 formed of quartz pipes that penetrate a side wall of the manifold 8, are bent, and extend upward. A plurality of gas distribution holes 30A and a plurality of gas distribution holes 32A are provided in the gas distribution nozzles 30 and 32, respectively, to be spaced apart from one another at predetermined intervals. A gas may be nearly uniformly distributed from the gas distribution holes 30A and 32A in a horizontal direction.

Meanwhile, a nozzle accommodating recess portion 34 is provided at a part of a side wall of the processing container 4 in a heightwise direction, and a long thin exhaust port 36 provided by vertically cutting off the side wall of the processing container 4 to evacuate the inside of the processing container 4 is provided at the opposite side of the processing container 4 to face the nozzle accommodating recess portion 34. In detail, the nozzle accommodating recess portion 34 is provided by vertically cutting off the side wall of the processing container 4 by a predetermined width to form a long thin opening 38 and attaching a long thin dividing wall 40, which is formed of, e.g., quartz and has a cross-section of a recess shape, in an airtight manner to an external wall of the processing container 4 through a welding process to externally cover the opening 38.

Accordingly, a part of the side wall of the processing container 4 is externally recessed so that the nozzle accommodating recess portion 34, which has one open side for communication with the processing container 4, may be provided integrally with the processing container 4. In other words, an inner space of the dividing wall 40 integrally communicates with the inside of the processing container 4. Also, as shown in FIG. 2, the gas distribution nozzles 30 and 32 are collaterally provided in the nozzle accommodating recess portion 34.

Meanwhile, an exhaust port cover member 42, which is formed of quartz and molded to have a U-shaped cross-section, is attached to the exhaust port 36 provided to face the opening 38 to cover the exhaust port 36 through a welding process. The exhaust port cover member 42 extends upward along the side wall of the processing container 4, and a vacuum exhaust system 46 is provided in a gas outlet 44 provided above the processing container 4. The vacuum exhaust system 46 includes an exhaust passage 48 connected to the gas outlet 44, and a pressure control valve 50 and a vacuum pump 52 are provided in the exhaust passage 48 to hold the inside of the processing container 4 at a predetermined pressure and perform a vacuum suction of the inside of the processing container 4. A heating unit 54 having a cylindrical shape and heating the processing container 4 and the semiconductor wafers W placed inside the processing container 4 is provided to surround the processing container 4.

A gas supply apparatus 60 according to the present invention is provided to supply gas necessary for a thermal treatment of the processing container 4. The gas supply apparatus 60 includes a raw material gas supply system 62 for supplying a raw material gas and a reaction gas supply system 64 for supplying a reaction gas to react with the raw material gas. In detail, the raw material gas supply system 62 includes a raw material storage tank 68 for storing a liquid or solid raw material 66. The raw material storage tank 68 may be referred to as an ample or a reservoir. Examples of the raw material 66 may include ZrCp(NMe₂)₃[cycolpentadienyl.tris(dimethylamino)zirconium] or Zr(MeCp)(NMe₂)₃[methylcycolpentadienyl.tris(dimethylamino)zirconium] that are liquid organic compounds of zirconium, or Ti(MeCp)(NMe₂)₃[methylcycolpentadienyl.tris(dimethylamino)titanium]. A raw material heater 69 is provided in the raw material storage tank 68 to form a raw material gas by heating and vaporizing the raw material 66 within a range in which the raw material 66 is not pyrolyzed. Here, the raw material 66 is heated at a temperature, e.g., between about 80 and about 120° C.

A raw material gas passage 70 is provided to connect the raw material storage tank 68 and a gas distribution nozzle 30 provided at one side of the gas inlet portion 28 provided in the processing container 4. First and second opening/closing valves 72 and 74 are sequentially provided in the raw material gas passage 70 toward a lower stream side of the raw material gas passage 70 from an upper stream side thereof to be spaced apart from each other, thereby controlling a flow of the raw material gas.

A gas inlet 76 provided at the upper steam of the raw material gas passage 70 is positioned in an upper space 68A inside the raw material storage tank 68 to discharge the raw material gas generated in the upper space 68A. A passage heater (not shown), e.g., a tape heater, is provided in the raw material gas passage 70 along the raw material gas passage 70 to heat the raw material gas passage 70 to a temperature in a range, e.g., between about 120 and 150° C., thereby preventing the raw material gas from being liquefied.

A carrier gas passage 78 is connected to the raw material storage tank 68 to introduce a carrier gas into the raw material storage tank 68. A gas outlet 80 provided at a leading end of the carrier gas passage 78 is positioned in the upper space 68A of the raw material storage tank 68. Also, the gas outlet 80 may be soaked in the liquid raw material 66 to bubble the carrier gas. A flow controller 82, for example, a mass flow controller, a first opening/closing valve 84, and a second opening/closing valve 86 for controlling a flow rate of gas toward a lower stream side of the carrier gas passage 78 from an upper stream side thereof are sequentially provided in the middle of the carrier gas passage 78.

Argon gas is used as the carrier gas. However, the present invention is not limited thereto, and any of other rare gases, e.g., He, may be used. Also, a bypass passage 88 is provided to connect the carrier gas passage 78 between the first opening/closing valve 84 and the second opening/closing valve 86 and the raw material gas passage 70 between the first opening/closing valve 72 and the second opening/closing valve 74, and a bypass opening/closing valve 90 is provided in the middle of the bypass passage 88.

Also, a pressure control gas passage 92 for supplying a pressure control gas is connected to a lower stream side of the second opening/closing valve 74 of the raw material gas passage 70. A flow controller 94, for example, a mass flow controller, and an opening/closing valve 96 toward a lower stream side of the pressure control gas passage 92 from an upper stream side thereof are sequentially provided in the pressure control gas passage 92. An inert gas, e.g., N₂ gas is used as the pressure control gas. A rare gas, e.g., Ar, instead of N₂ gas may be used as the pressure control gas.

A vent passage 98 is connected to the raw material gas passage 70 between the second opening/closing valve 74 of the raw material gas passage 70 and a connection point to the raw material gas passage 70 of the bypass passage 88. A lower stream side of the vent passage 98 is connected to the exhaust passage 48 between the pressure control valve 50 and the vacuum pump 52 of the vacuum exhaust system 46 to perform a vacuum suction of the inside of the vent passage 98. A vent opening/closing valve 100 is provided in the middle of the vent passage 98. Meanwhile, the reaction gas supply system 64 includes a reaction gas passage 102 connected to the gas distribution nozzle 32. A flow controller 104, e.g., a mass flow controller, and an opening/closing valve 106 are sequentially provided in the middle of the reaction gas passage 102 to supply the reaction gas while controlling a flow rate of the reaction gas when required. A branched passage 108 is provided to be branched from the middle of the reaction gas passage 102. A flow controller 110 and an opening/closing valve 112, e.g., a mass flow controller, are sequentially provided in the middle of the branched passage 108 to supply a purge gas while controlling a flow rate of the purge gas when required.

An oxidized gas, e.g., as O₃, is used as the reaction gas, and a zirconium oxide film may be formed by oxidizing a raw material containing Zr. Also, for example, N₂ gas may be used as the purge gas. In the gas supply apparatus 60, opening/closing operations of each opening/closing valve may be controlled by a valve control unit 114.

The overall operation of the thermal treatment apparatus 2 configured as described above may be controlled by an apparatus controller 116, e.g., a computer, and a program of the computer for executing the operation of the thermal treatment apparatus 2 is stored in a storage medium 118. The storage medium 118 may be constituted of, e.g., a flexible disc, a compact disc (CD), a hard disc, a flash memory, or a digital versatile disc (DVD). In detail, by commands from the apparatus controller 116 and the valve control unit 114, which is under the control of the apparatus controller 116, the starting and the stopping of supply of each gas is controlled, a flow rate of each gas is controlled, and a temperature and pressure of a process are controlled. As described above, the valve control unit 114 is controlled by the apparatus controller 116.

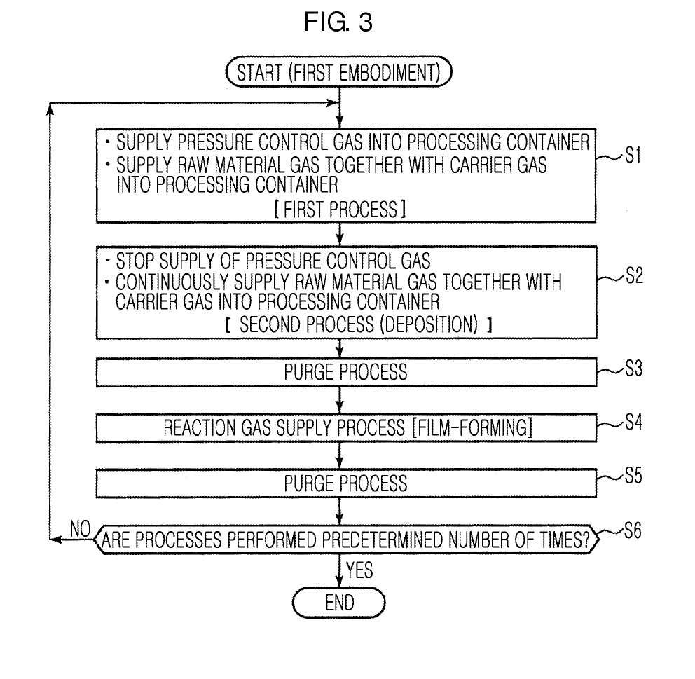

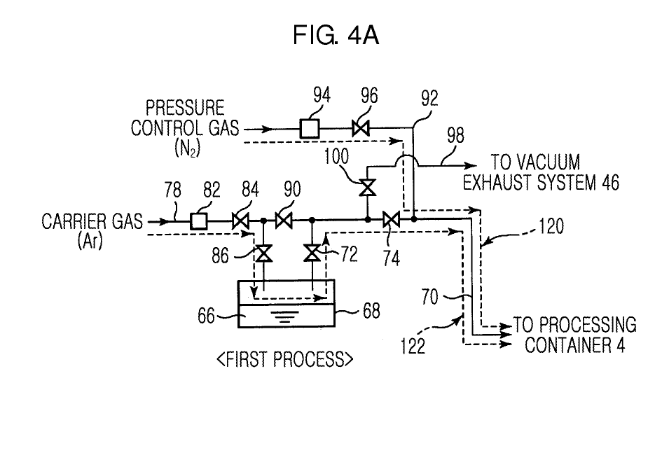

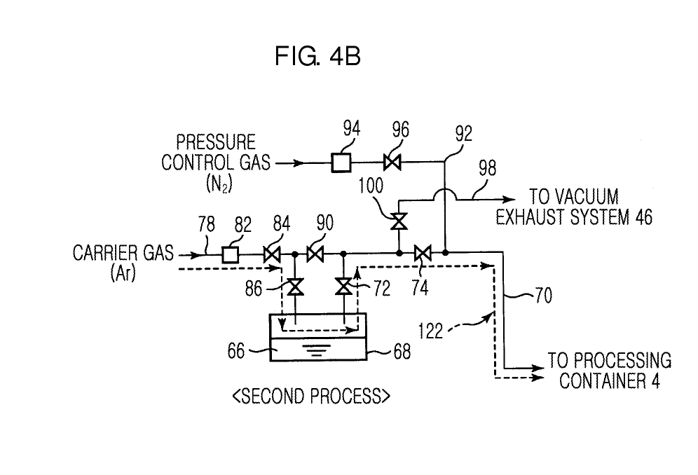

Next, a method of the present invention performed by using the thermal treatment apparatus 2 configured as described above will be described with reference to FIGS. 3 through 4B.

### First Embodiment

First, a thermal treatment method including an embodiment of a gas supply method according to the present invention will be described below. FIG. 3 is a flowchart for describing a thermal treatment method including the embodiment of the gas supply method according to the present invention FIGS. 4A and 4B are schematic diagrams for describing flow of gas using the embodiment of the gas supply method according to the present invention. In FIGS. 4A and 4B, the flow of gas is indicated by a dotted line arrow. A case where ZrCp(NMe₂)₃ is used as a raw material and a zirconium oxide thin film is formed by using O₃, that is an oxidized gas, as a reaction gas will be described as an example.

In detail, the thin film may be formed by repeatedly performing a plurality of times one cycle including a process of alternately supplying the raw material gas and the reaction gas (O₃) in a pulse shape in a predetermined supplying time and a process of stopping the supply of the raw material gas and the reaction gas (O₃). In particular, in the method of the present invention, a differential pressure in a gas passage is prevented from being generated as much as possible when starting the supply of the raw material gas.

First of all, the wafer boat 12 on which a plurality of, e.g., 50 to 100 sheets of, wafers W having a size of 300 mm at room temperature are placed is moved up from the lower side of the processing container 4 to be loaded into the processing container 4 which is previously set to a predetermined temperature, and the lower opening portion of the manifold 8 is closed by the cover unit 18, thereby sealing the processing container 4.

The inside of the processing container 4 may be held at pressure in a range between about 0.1 and 3 torr by performing a vacuum suction of the inside of the processing container 4, and a processing temperature may be held by increasing temperatures of the wafers W by increasing power to be supplied to the heating unit 54.

The raw material gas and O₃ are alternately supplied into the processing container 4, as described above, by driving the raw material gas supply system 62 and the reaction gas supply system 64 of the gas supply apparatus 60 to deposit the zirconium oxide thin film on surfaces of the wafers W. In detail, the raw material 66 is heated by the raw material heater 69 in the raw material storage tank 68 of the raw material gas supply system 62, and thus, the raw material gas is generated in the raw material storage tank 68.

When a film-forming process (thermal treatment) is started, a first process (process S1) of FIG. 3 is performed. In other words, a pressure at the lower stream side of the raw material gas passage 70 may be previously increased by opening the opening/closing valve 96 of the pressure control gas passage 92 and supplying a pressure control gas constituted of N₂ into the processing container 4 as indicated by an arrow 120 (see FIG. 4A). At the same time, the first and second opening/closing valves 84 and 86 of the carrier gas passage 78 are opened, a carrier gas constituted of Ar flows into the raw material storage tank 68, the first and second opening/closing valves 72 and 74 of the raw material gas passage 70 are opened, and the raw material gas inside the raw material storage tank 68 flows together with the carrier gas into the processing container 4 as indicated by an arrow 122 (process S1).

As such, the pressure control gas and the carrier gas accompanied with the raw material gas are simultaneously supplied into the processing container 4. At this time, a flow rate of the pressure control gas is in a range between 1 and 10 slm, e.g., 5 slm. A flow rate of the carrier gas is in a range between 2 and 15 slm, e.g., 7 slm, which is greater than that of the pressure control gas. A duration when a gas is supplied is a small period of time in a range, for example, between 1 and 10 seconds. The duration may be, for example, about 5 seconds. By supplying the carrier gas at a large amount of 7 slm as described above, a large amount of raw material gas may be supplied.

As such, by simultaneously supplying the pressure control gas and the carrier gas, a differential pressure between the lower stream side of the raw material gas passage 70 adjacent to the processing container 4 and the inside of the carrier gas passage 78, in detail, a differential pressure between the gas inlet 76 of the raw material storage tank 68 and an inlet of the gas distribution nozzle 30 may be suppressed by an amount of the supplied pressure control gas, thereby preventing particles from being generated because of the raw material gas that changes into mist due to the differential pressure. When the duration of the first process is less than 1 second, a differential pressure suppression effect may be remarkably decreased. Also, when the duration of the first process is longer than 10 seconds, a throughput may be decreased more than necessary.

As such, if the first process is performed for about 5 seconds, a second process (process S2) of FIG. 3 is performed. In other words, if the first process is performed for about 5 seconds, a supply of the pressure control gas is stopped as shown in FIG. 4B by immediately closing the opening/closing valve 96 of the pressure control gas passage 92. Then, the raw material gas accompanied with the carrier gas is continuously supplied into the processing container 4, and thus a large amount of raw material gas is deposited onto the surfaces of the wafers W. The duration of the second process is in a range of, for example, between 50 and 200 seconds, and here, for example, 100 seconds.

If the second process is finished, a purge process (process S3) for exhausting a residual gas inside the processing container 4 when supply of the carrier gas and the raw material gas is stopped is performed. In the purge process, supply of all gases is stopped to exhaust the residual gas inside the processing container 4. Alternatively, an inert gas, e.g., N₂, may be supplied from the pressure control gas passage 92 into the processing container 4 to be replaced with the residual gas, or these two methods may be combined. A flow rate of the N₂ gas is in a range between 0.5 and 15 slm, and here, for example, 10 slm. A duration of the purge process is in a range between 4 and 120 seconds, and in this case, about 60 seconds.

Also, in the purge process (process S3), in order to exhaust the raw material gas remaining inside the raw material gas passage 70, the first and second opening/closing valves 72 and 74 of the raw material gas passage 70 are closed, the first opening/closing valve 84 of the carrier gas passage 78 is opened, the second opening/closing valve 86 is closed, and the bypass opening/closing valve 90 and the vent opening/closing valve 100 are opened. Accordingly, the carrier gas flows into the vent passage 98 via a part of the bypass passage 88 and a part of the raw material gas passage 70 without being introduced into the raw material storage tank 68, and thus, the carrier gas is exhausted to the vacuum exhaust system 46. A flow rate of the carrier gas is in a range between 2 and 15 slm, for example, about 10 slm.

If the purge process (process S3) is finished as described above, a reaction gas supply process (process S4) is performed. A reaction gas constituted of O₃ is supplied into the processing container 4 by using the reaction gas supply system 64. Accordingly, the raw material gas deposited onto the surfaces of the wafers W reacts with O₃, thereby forming a zirconium oxide thin film. A duration of the reaction gas supply process is in a range between 50 and 200 seconds, and in this case, for example, about 100 seconds.

If the reaction gas supply process (process S4) is finished, a purge process (process S5) for exhausting a residual gas inside the processing container 4 is performed. The purge process (process S5) is performed in the same way as the above-described purge process (process S3). When an inert gas is used, N₂ gas may be supplied from the branched passage 108 of the reaction gas supply system 64.

If the purge process (process S5) is finished, it is determined how many times the above-described processes S1 to S5 are performed (process S6). If the above-described processes S1 to S5 are not performed as often as predetermined number of times (NO), the zirconium oxide thin film is deposited by repeatedly performing the above-described processes S1 to S5. If the above-described processes S1 to S5 are performed as often as predetermined number of times (YES), the thermal treatment of the film-forming process is finished.

As described above, pressure inside the processing container 4 before starting the process S1 is as low as about 0.1 to about 3 torr. However, in process S1, a large amount of raw material gas is supplied by supplying a large amount of carrier gas, and at the same time, the pressure control gas temporarily flows to the upper stream side of the raw material gas passage 70, and thus differential pressure between the inside of the raw material gas passage 70 and the inside of the raw material storage tank 68 may be decreased by pressure of the pressure control gas.

In other words, a differential pressure between the lower stream side of the raw material gas passage 70 adjacent to the processing container 4 and the inside of the carrier gas passage 78, in detail, a differential pressure between the gas inlet 76 of the raw material storage tank 68 and an inlet of the gas distribution nozzle 30, may be suppressed by an amount of the supplied pressure control gas, thereby preventing particles from being generated because of the raw material gas that changed into mist due to the differential pressure. As such, even though the large amount of raw material gas flows, generation of mist of the raw material gas and generation of particles may be prevented.

As such, in the gas supply apparatus including the raw material gas supply system 62 for supplying the raw material gas generated from the raw material 66 inside the raw material storage tank 68 into the processing container 4 performing thermal treatment on the objects to be processed (wafers W) by using the carrier gas, the first process for starting the supply of the pressure control gas into the processing container 4 and simultaneously starting the supply of the raw material gas into the processing container 4 from the raw material storage tank 68 by using the carrier gas is performed, and then the second process for stopping the supply of the pressure control gas is performed, and thus, when starting the supply of the raw material gas, a differential pressure between a supply side of the carrier gas and the processing container 4 may be decreased, thereby preventing generation of particles.

### Second Embodiment

Next, a thermal treatment method including another embodiment of a gas supply method according to the present invention will be described. First, in the previous embodiment described with reference to FIGS. 3 and 4, the differential pressure inside the raw material gas passage 70 is suppressed by simultaneously supplying the pressure control gas and the raw material gas accompanied with the carrier gas toward the processing container 4 in process S1. However, the present invention is not limited thereto, and a large amount of the carrier gas is previously supplied into the raw material gas passage 70 before supplying the raw material gas so that the differential pressure generated when starting the supply of the raw material gas may further be suppressed.

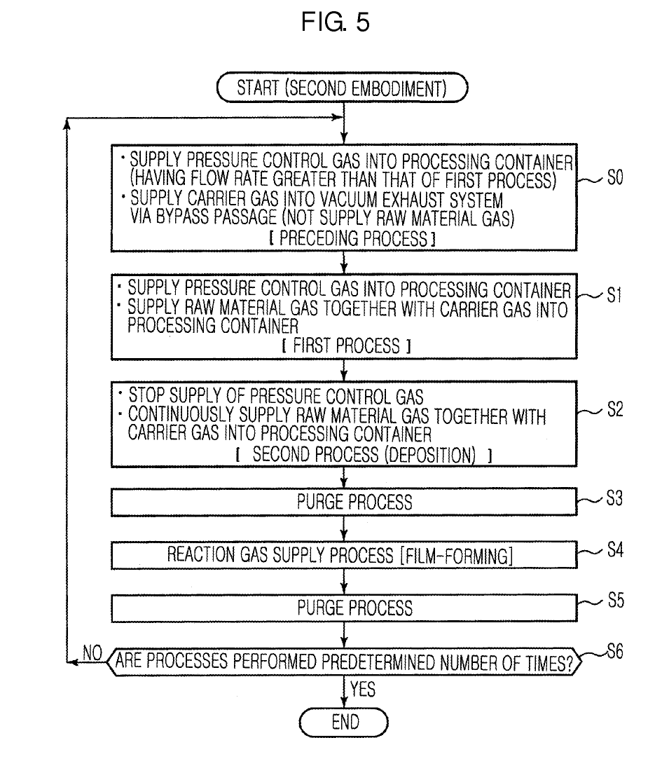

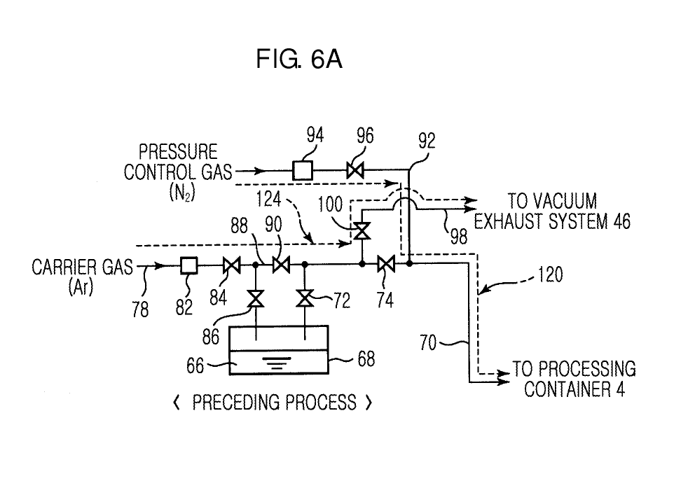

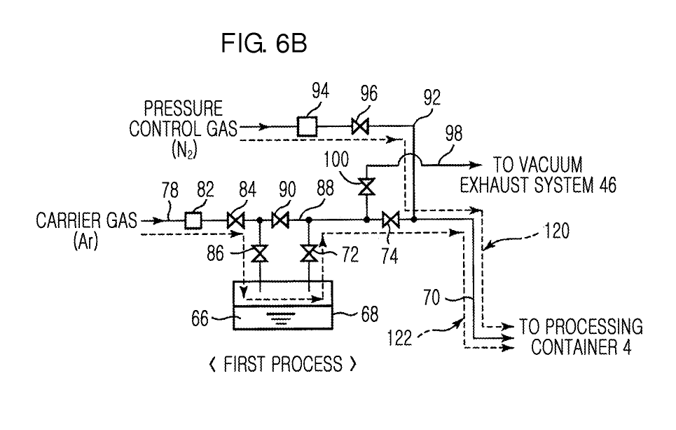

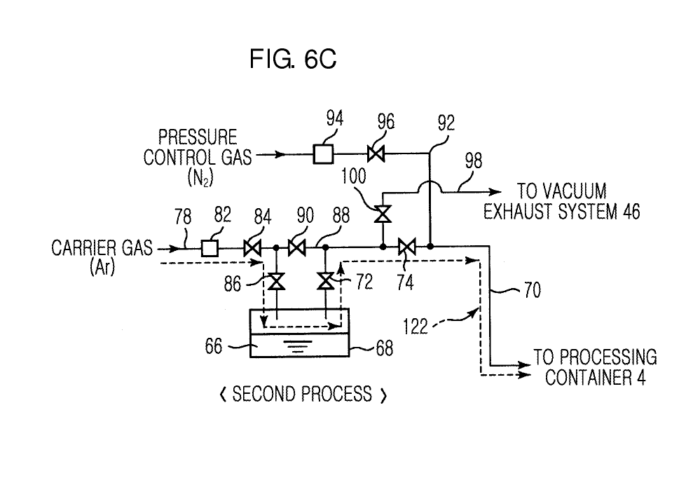

FIG. 5 is a flowchart for describing a thermal treatment method including another embodiment of a gas supply method according to the present invention. FIGS. 6A through 6C are schematic diagrams for describing flow of gas using the gas supply method of FIG. 5. In FIGS. 6A through 6C, the flow of gas is indicated by a dotted line arrow. Also, like reference numerals in the following description denote like elements in FIGS. 3 through 4B, and thus they will not be explained again.

FIGS. 6B and 6C are completely the same as FIGS. 4A and 4B, respectively. In the current embodiment, as shown in FIG. 5 through 6C, before performing process S1, that is, just before performing process S1, a preceding process (process S0) for supplying a carrier gas to the vent passage 98 via the bypass passage 88 and supplying a pressure control gas into the processing container 4 is performed.

In other words, if a film-forming process (thermal treatment) is started, the opening/closing valve 96 of the pressure control gas passage 92 is opened and the pressure control gas constituted of N₂ flows into the processing container 4 as indicated by an arrow 120 to perform the preceding process (process S0) as shown in FIG. 6A. However, in this case, a flow rate of the pressure control gas is set to be greater than that of the first process to be performed just after the preceding process. At the same time, all of the first opening/closing valve 84 of the carrier gas passage 78, the bypass opening/closing valve 90 of the bypass passage 88, and the vent opening/closing valve 100 of the vent passage 98 are opened to supply a large amount of the carrier gas to the vacuum exhaust system 46 as indicated by an arrow 124.

In this case, the second opening/closing valve 86 of the carrier gas passage 78 and the first and second opening/closing valves 72 and 74 of the raw material gas passage 70 are closed so that the raw material gas is not supplied and the carrier gas is supplied into a part of the raw material gas passage 70 but not supplied into the processing container 4.

At this time, a flow rate of the pressure control gas is in a rage between 1 and 15 slm, e.g., 3 slm, that is greater than that of the first process. A flow rate of the carrier gas is in a range between 2 and 15 slm, e.g., 7 slm, that is the same as that of the first process to be performed immediately after the preceding process. A duration for supplying a gas is in a range between 1 and 10 seconds, and in this case, for example, 5 seconds. When the duration of the preceding process is less than 1 second, there is no effect of performing the preceding process. Also, when the duration of the preceding process is longer than 10 seconds, a throughput may be decreased more than necessary.

As such, if the preceding process is performed for about 5 seconds, the subsequent processes are performed in the same way as the above-described processes S1 to S6. For example, the method proceeds to the first process (process S1), and the first process is performed for about 4 seconds. In other words, both the bypass opening/closing valve 90 and the vent opening/closing valve 100 are changed to a close state and both the second opening/closing valve 86 of the carrier gas passage 78 and the first and second opening/closing valves 72 and 74 of the raw material gas passage 70 are changed to an open state so that the raw material gas inside the raw material storage tank 68 flows together with the carrier gas into the processing container 4 as indicated by the arrow 122 (process S1).

At this time, the flow rate of the pressure control gas that has been supplied at the flow rate of 3 slm is decreased to 1 slm so that a total amount of a gas supplied into the processing container 4 may not rapidly excessively increased. Then, until the thermal treatment is finished, processes S0 to S6 are repeatedly performed predetermined number of times.

In the current embodiment, by performing the preceding process (process S0) just before the first process (process S1), the pressure control gas previously flows to most areas inside the raw material gas passage 70 for a short time (the carrier gas is discharged via the vent passage 98), and in this state, the carrier gas including the raw material gas flows into the processing container 4, and thus differential pressure generated between the upper stream side of the raw material gas passage 70 and the lower stream side thereof may further be suppressed compared to the previous embodiment. Accordingly, the same effects as in the previous embodiment may be obtained, and also an effect of preventing generation of mist or particles may be further improved.

Actually, when a film-forming process using an ALD method is performed in 20 cycles by using the gas supply method of the current embodiment, in a conventional gas supply method, the number of particles having a size equal to or greater than 0.08 μm on a wafer is 28, while in the present invention, the number of particles is decreased to 5, and thus, a satisfactory result may be obtained.

Meanwhile, in a conventional film-forming method, when a flow rate of a carrier gas is low, for example, when the flow rate of the carrier gas is about 1 slm, the number of particles is about 10. However, a raw material gas having a sufficient flow rate may not be supplied to correspond to an increase in the number of wafers to be simultaneously processed, miniaturization of a device, and a high-aspect-ratio, and thus uniformity of a thickness of a film and a step coverage may not be sufficiently obtained. On the other hand, in the present invention, a raw material gas having a sufficient flow rate may be supplied to correspond to an increase in the number of wafers to be simultaneously processed, miniaturization of a device, and a high-aspect-ratio without generating particles, uniformity of a thickness of a film and a step coverage may be sufficiently obtained.

### Third Embodiment

Next, a thermal treatment method including another embodiment of a gas supply method according to the present invention will be described. First, in the preceding process of the previous embodiment described with reference to FIGS. 5 through 6C, although the pressure control gas and the carrier gas are supplied, the supply of the carrier gas may be stopped and only the pressure control gas may be supplied so that a differential pressure generated when starting the supply of the raw material gas may be further suppressed.

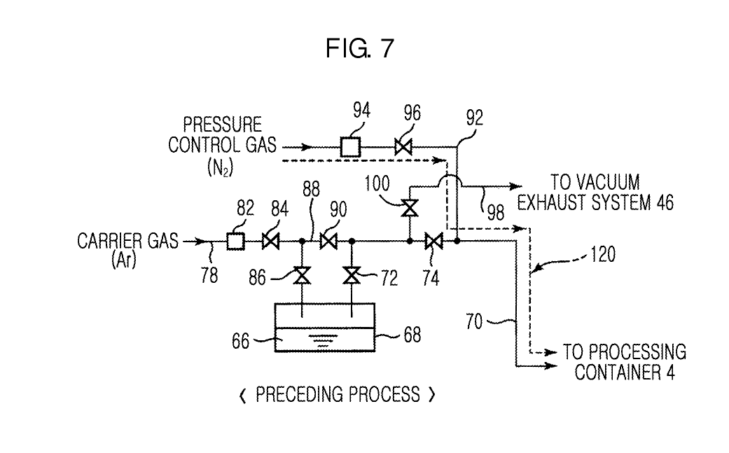

FIG. 7 is a schematic diagram for describing flow of gas of a preceding process using another embodiment of a gas supply method according to the present invention. In FIG. 7, the flow of gas is indicated by a dotted line arrow. Also, like reference numerals in the following description denote like elements in FIGS. 3 to 6C, and thus, they will not be explained again. In the current embodiment, as shown in FIG. 7, before performing process S1, that is, immediately before performing process S1, a preceding process (process S0) for supplying only the pressure control gas into the processing container 4 is performed.

In other words, if a film-forming process (thermal treatment) is started, the opening/closing valve 96 of the pressure control gas passage 92 is opened and the pressure control gas constituted of N₂ flows into the processing container 4 as indicated by an arrow 120 to perform the preceding process (process S0) as shown in FIG. 7. However, in this case, a flow rate of the pressure control gas is set to be greater than that of the first process to be performed just after the preceding process. Here, the current embodiment is performed in a different way from the previous embodiment, and all of the first opening/closing valve 84 of the carrier gas passage 78, the bypass opening/closing valve 90 of the bypass passage 88, and the vent opening/closing valve 100 of the vent passage 98 are closed not to supply the carrier gas.

Various process conditions at this time are the same as those of the preceding process performed in the previous embodiment. After the preceding process is performed, the same processes as processes S1 to S6 described in the previous embodiment are performed. In this case, the same effects as in the previous embodiment may be obtained.

In the previous embodiments described with reference to FIGS. 3 and 5, two purge processes (processes S3 and S5) are combined, but any one of or both purge processes (processes S3 and S5) may be omitted.

Also, in the embodiment described with reference to FIG. 1, although many opening/closing valves are provided in the gas supply apparatus 60, two opening/closing valves provided in a portion where two passages are branched may be used as a single three-way valve. In detail, for example, the second opening/closing valve 74 of the raw material gas passage 70 and the vent opening/closing valve 100 of the vent passage 98 may be replaced with a single three-way valve.

Also, in the embodiment described with reference to FIG. 1, the thermal treatment apparatus having a double-tube structure has been described. However, the present invention is not limited thereto and may be applied to, for example, a thermal treatment apparatus having a single-tube structure. In addition, in the present invention, an ALD film-forming process in which processes S1 to S6 or processes S0 to S6 are repeatedly performed as thermal treatment has been described. However, the present invention is not limited thereto and may be applied to a film-forming process for performing processes S1 to S6 or processes S0 to S6 (processes S3 and S5 may be omitted) are performed only once.

Furthermore, in the present invention, the batch-type thermal treatment apparatus for simultaneously processing a plurality of the semiconductor wafers W has been described. However, the present invention is not limited thereto and may be applied to a single-wafer-type thermal treatment apparatus for individually processing each semiconductor wafer W. In addition, in the present invention, an organic metal material including zirconium is used as a raw material. However, the present invention is not limited thereto, and an organic metal material including one or a plurality of metal materials selected from Zr, Hf, Ti, and Sr may be used as a raw material.

Also, in the present invention, although a semiconductor wafer is used as an object to be processed, the semiconductor wafer may include a silicon substrate or a compound semiconductor substrate such as GaAs, SiC, or GaN. Also, the present invention is not limited thereto and may be applied to a glass substrate or a ceramic substrate used in a liquid crystal display apparatus.

According to the gas supply apparatus, the thermal treatment apparatus, the gas supply method, and the thermal treatment method of the present invention, the following effects may be obtained.

In a gas supply apparatus including a raw material gas supply system for supplying a raw material gas generated from a raw material inside a raw material storage tank into a processing container for performing thermal treatment on objects to be processed by using a carrier gas, a first process for starting supply of a pressure control gas into the processing container and simultaneously starting supply of the raw material gas into the processing container from the raw material storage tank by using the carrier gas is performed, and then a second process for stopping the supply of the pressure control gas is performed, and thus, when starting the supply of the raw material gas, a differential pressure between a supply system of the carrier gas and the processing container may be decreased, thereby preventing generation of particles.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A gas supply method used by a gas supply apparatus which comprises a raw material storage tank storing a raw material, a carrier gas passage introducing a carrier gas into the raw material storage tank, a raw material gas passage connecting the raw material storage tank and a processing container performing thermal treatment on an object to be processed, and a pressure control gas passage connected to the raw material gas passage and supplying a pressure control gas, the gas supply method comprising:
starting supply of the pressure control gas through the pressure control gas passage and a downstream side of the raw material gas passage into the processing container and simultaneously starting supply of the raw material gas through an upstream side and the downstream side of the raw material gas passage into the processing container from the raw material storage tank by using the carrier gas such that the pressure in an downstream side of the raw material gas passage is increased due to the pressure control gas, thereby decreasing a pressure difference between the upstream side and the downstream side of the raw material gas passage when starting the supply of the raw material gas, and
after the starting the supply of the pressure control gas and the starting the supply of the raw material gas, stopping the supply of the pressure control gas while performing the supply of the raw material gas.

2. A gas supply method used by a gas supply apparatus which comprises a raw material storage tank storing a raw material, a carrier gas passage introducing a carrier gas into the raw material storage tank, a raw material gas passage connecting the raw material storage tank and a processing container performing thermal treatment on an object to be processed, and a pressure control gas passage connected to the raw material gas passage and supplying a pressure control gas, the gas supply method comprising:
supplying the pressure control gas through the pressure control gas passage and a downstream side of the raw material gas passage into the processing container such that the pressure in the downstream side of the raw material gas passage is increased due to the pressure control gas;
while performing the supplying of the pressure control gas, starting supply of the raw material gas through an upstream side and the downstream side of the raw material gas passage into the processing container from the raw material storage tank by using the carrier gas such that, when starting the supply of the raw material gas, a pressure difference between the upstream side and the downstream side of the raw material gas passage is decreased; and
while performing the supply of the raw material gas, stopping the supply of the pressure control gas.

3. The gas supply method of claim 2,
wherein the gas supply apparatus further comprising:
a bypass passage which connects the carrier gas passage and the raw material gas passage to bypass the raw material storage tank; and
a vent passage which is connected to the raw material gas passage and is to be a vacuum suction,
wherein, in the supplying of the pressure control gas, the carrier gas is further supplied toward the vent passage via the bypass passage.

4. The gas supply method of claim 2, wherein a flow rate of the pressure control gas in the supplying of the pressure control gas is set to be greater than that of the pressure control gas in the starting of the supply of the raw material gas.

5. The gas supply method of claim 1,
wherein the gas supply apparatus further comprises a reaction gas supply system supplying a reaction gas to react with the raw material gas into the processing container,
wherein the gas supply method further comprises supplying the reaction gas into the processing container after the stopping of the supply of the pressure control gas.

6. The gas supply method of claim 5, further comprising a purge process of exhausting a residual atmosphere of the processing container immediately after performing any one of the stopping of the supply of the pressure control gas and the supplying of the reaction gas.

7. The gas supply method of claim 1, wherein the starting of supply of the pressure control gas and the stopping of the supply of the pressure control gas are sequentially repeated.

8. A thermal treatment method used to perform thermal treatment on an object to be processed by using the gas supply method of claim 1.
